(19) United States
(12) Patent Application Publication
(10) Pub. No.: US 2024/0088847 A1
(43) Pub. Date: Mar. 14, 2024

(54) AMPLIFICATION CIRCUIT AND COMMUNICATION DEVICE

(71) Applicant: Murata Manufacturing Co., Ltd., Kyoto (JP)

(72) Inventors: Yasutaka SUGIMOTO, Kyoto (JP); Koji NASU, Kyoto (JP)

(21) Appl. No.: 18/457,690

(22) Filed: Aug. 29, 2023

(30) Foreign Application Priority Data
Sep. 8, 2022 (JP) 2022-143026

(51) Int. Cl. H03F 3/24

(52) U.S. Cl. CPC H03F 3/245; H03F 2200/451

(57) ABSTRACT

An amplification circuit includes an amplification transistor connected to a signal input terminal, a power supply circuit configured to supply a bias voltage to the amplification transistor, a resistor disposed in series to a bias path connecting the power supply circuit and the amplification transistor, a transistor that is connected to the bias path and the power supply circuit and that is a simulated transistor for the amplification transistor, and a detection diode connected to the signal input terminal and the bias path between the resistor and a gate of the amplification transistor.

### CROSS REFERENCE TO RELATED APPLICATION

This application claims priority from Japanese Patent Application No. 2022-143026 filed on Sep. 8, 2022. The content of this application is incorporated herein by reference in its entirety.

### BACKGROUND ART

The present disclosure relates to an amplification circuit and a communication device.

Japanese Unexamined Patent Application Publication No. 2005-123861 discloses a radio-frequency power amplification circuit including a field-effect amplification transistor for amplifying a radio-frequency signal, a simulated transistor having the same configuration as the amplification transistor, a reference bias circuit, a bias correction circuit, and a current simulation circuit. Since the simulated transistor has the same temperature variation and the same process variation as the amplification transistor, the variation in the amplification characteristics of the radio-frequency power amplification circuit can be suppressed by correcting the deviation of a bias point of the amplification transistor.

However, in the power amplification circuit disclosed in Japanese Unexamined Patent Application Publication No. 2005-123861, it is difficult to suppress the distortion of output characteristics of a radio-frequency signal due to the nonlinearity of the amplification transistor.

### BRIEF SUMMARY

The present disclosure provides an amplification circuit with which the distortion of the output characteristics of a radio-frequency signal is suppressed and a communication device using the amplification circuit.

To achieve the above object, an amplification circuit according to an aspect of the present disclosure includes a first transistor that is connected to a radio-frequency input terminal and that is a field-effect transistor, a power supply circuit configured to supply a bias voltage to the first transistor, a first resistor disposed in series to a bias path connecting the power supply circuit and the first transistor, a second transistor that is connected to the bias path and the power supply circuit and that is a simulated transistor for the first transistor, and a first diode connected to the radio-frequency input terminal and the bias path between the first resistor and a gate of the first transistor.

An amplification circuit according to an aspect of the present disclosure includes a first transistor that is connected to a radio-frequency input terminal and that is a field-effect transistor, a power supply circuit configured to supply a bias voltage to the first transistor, a second transistor that is connected to the power supply circuit and that is a simulated transistor for the first transistor, a first diode connected between the power supply circuit and the radio-frequency input terminal, a second diode that is a simulated diode for the first diode, and a difference detection circuit that is connected between the power supply circuit and each of the first diode and the second diode and that is configured to output a differential current between a first current flowing through the first diode and a second current flowing through the second diode to the power supply circuit.

According to the present disclosure, there can be provided an amplification circuit and a communication device with which the distortion of the output characteristics of a radio-frequency signal is suppressed.

### BRIEF DESCRIPTION OF THE DRAWINGS

FIG. 1 is a diagram illustrating the circuit configuration of an amplification circuit according to a first embodiment and a communication device;

FIG. 2A is a diagram illustrating a relationship between a gate-to-source voltage and a gate-to-source capacitance of an amplification transistor according to a comparative example;

FIG. 2B is a diagram illustrating a relationship between output power and a gate-to-source capacitance of an amplification circuit according to a comparative example;

FIG. 2C is a diagram illustrating a relationship between output power and amplitude modulation-phase modulation conversion (AM-PM) characteristics of an amplification circuit according to a comparative example;

FIG. 3A is a diagram illustrating a relationship between a gate-to-source voltage and a gate-to-source capacitance of an amplification transistor according to the first embodiment;

FIG. 3B is a diagram illustrating relationships between output power and gate-to-source voltage of an amplification circuit according to the first embodiment and an amplification circuit according to a comparative example;

FIG. 3C is a diagram illustrating relationships between output power and gate-to-source capacitance of an amplification circuit according to the first embodiment and an amplification circuit according to a comparative example;

FIG. 3D is a diagram illustrating relationships between output power and amplitude modulation-phase modulation conversion (AM-PM) characteristics of an amplification circuit according to the first embodiment and an amplification circuit according to a comparative example;

FIG. 4 is a diagram illustrating a circuit configuration of an amplification circuit according to a first example;

FIG. 5A is a diagram illustrating a relationship between output power and a diode current of an amplification circuit according to the first example;

FIG. 5B is a diagram illustrating a relationship between output power and a diode current of an amplification circuit when a diode current is controlled to be constant without necessarily the use of a diode replica;

FIG. 6A is a diagram illustrating a relationship between output power and a bias voltage of an amplification circuit according to the first example;

FIG. 6B is a diagram illustrating relationships between output power and a gate-to-source capacitance of an amplification circuit according to the first example and an amplification circuit according to a comparative example;

FIG. 6C is a diagram illustrating relationships between output power and amplitude modulation-phase modulation conversion (AM-PM) characteristics of an amplification circuit according to the first example and an amplification circuit according to a comparative example;

FIG. 7 is a diagram illustrating a circuit configuration of an amplification circuit according to a second example;

FIG. 8A is a diagram illustrating a circuit configuration of a current source circuit according to the second example;

FIG. 8B is a diagram illustrating a circuit configuration of a modification of a current source circuit according to the second example;

FIG. 9 is a diagram illustrating a circuit configuration of a modification of a bias circuit according to the second example;

FIG. 10 is a diagram illustrating a circuit configuration of an amplification circuit according to a third example;

FIG. 11 is a diagram illustrating a circuit configuration of a modification of a bias circuit according to the third example;

FIG. 12 is a diagram illustrating a circuit configuration of an amplification circuit according to a second embodiment;

FIG. 13A is a diagram illustrating a relationship between output power and a bias voltage of an amplification circuit according to the second embodiment;

FIG. 13B is a diagram illustrating relationships between output power and a gate-to-source capacitance of an amplification circuit according to the second embodiment and an amplification circuit according to a comparative example; and

FIG. 13C is a diagram illustrating relationships between output power and an amplitude modulation-phase modulation conversion (AM-PM) characteristics of an amplification circuit according to the second embodiment and an amplification circuit according to a comparative example.

### DETAILED DESCRIPTION

In the following, embodiments of the present disclosure will be described in detail. Each of the embodiments to be described below illustrates a general or specific example. The numerical values, shapes, materials, constituent elements, the arrangement and connection manner of the constituent elements, and so forth to be described in the following embodiments are merely examples and are not intended to limit the present disclosure. Of the constituent elements in the following examples and modifications, constituent elements not described in the independent claims will be described as optional constituent elements. The sizes of the constituent elements illustrated in the drawings or the ratios between the sizes are not necessarily exact. In the drawings, elements that are substantially the same are denoted by the same reference numerals, and duplicate description may be omitted or simplified.

In the present disclosure, terminology representing the relationship between elements, such as parallel and vertical, terminology representing the shape of an element, such as rectangular, and the range of a numerical value mean not only an exact relationship, an exact shape, and an exact range, respectively, but also a substantially equivalent relationship, a substantially equivalent shape, and a substantially equivalent range, respectively, and, for example, a difference of small percent is included.

In the present disclosure, the expression “connected” includes not only the case in which a circuit element is directly connected to another circuit element via a connection terminal and/or a wiring conductor but also the case in which a circuit element is electrically connected to another circuit element via still another circuit element. The expression “is connected between A and B” denotes that a circuit element is connected to A and B on a path connecting A and B.

In the present disclosure, a “path” means a transmission line constituted by a wiring line through which a radio-frequency signal propagates, an electrode directly connected to the wiring line, a terminal directly connected to the wiring line or the electrode, and so forth.

In the present disclosure, the expression “a component A is placed in series to a path B” means that both a signal input end and a signal output end of the component A are connected to a wiring line, an electrode, or a terminal constituting the path B.

### First Embodiment

### <1. Circuit Configurations of Amplification Circuit 1 and Communication Device 4>

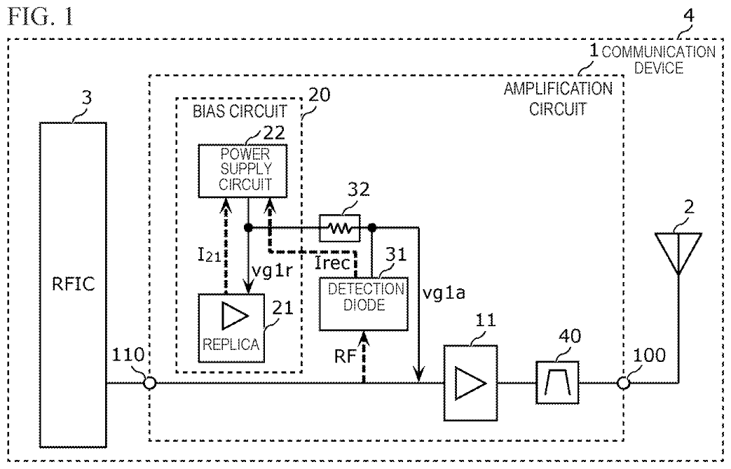

The amplification circuit 1 according to the present embodiment and the communication device 4 including the amplification circuit 1 will be described with reference to FIG. 1. FIG. 1 is a diagram illustrating the circuit configuration of the amplification circuit 1 according to the first embodiment and the communication device 4.

### <1.1 Circuit Configuration of Communication Device 4>

The communication device 4 corresponds to so-called user equipment (UE) and is typically, for example, a mobile phone, a smartphone, or a tablet computer. The communication device 4 includes the amplification circuit 1, an antenna 2, and a radio-frequency signal processing circuit (RFIC: radio frequency integrated circuit) 3.

The amplification circuit 1 transmits a radio-frequency signal between the antenna 2 and the RFIC 3. The circuit configuration of the amplification circuit 1 will be described below.

The antenna 2 is connected to an antenna connection terminal 100 of the amplification circuit 1. The antenna 2 receives a radio-frequency signal from the amplification circuit 1 and externally outputs the radio-frequency signal.

The RFIC 3 is an example of a signal processing circuit for processing a radio-frequency signal. Specifically, the RFIC 3 performs signal processing such as up-conversion upon a transmission signal input from a baseband signal processing circuit (BBIC: baseband integrated circuit: not illustrated) and outputs a transmission signal generated as a result of the signal processing to a signal input terminal 110 of the amplification circuit 1.

In the communication device 4 according to the present embodiment, the antenna 2 is an optional constituent element.

### <1.2 Circuit Configuration of Amplification Circuit 1>

Next, the circuit configuration of the amplification circuit 1 will be described. As illustrated in FIG. 1, the amplification circuit 1 includes an amplification transistor 11, a bias circuit 20, a detection diode 31, a resistor 32, a filter 40, the signal input terminal 110, and the antenna connection terminal 100.

The amplification transistor 11 is an example of a first transistor and is a field-effect transistor (FET) connected to the signal input terminal 110 (an example of a first radio-frequency input terminal). The amplification transistor 11 is, for example, an n-channel FET and has a gate connected to the signal input terminal 110.

The bias circuit 20 is configured to supply a bias voltage vg1a (first bias voltage) to the gate of the amplification transistor 11. The bias circuit 20 includes a transistor 21 and a power supply circuit 22.

The power supply circuit 22 is configured to supply a constant bias voltage vg1r (second bias voltage) to the gate of the transistor 21. The power supply circuit 22 is also configured to supply the bias voltage vg1a to the gate of the amplification transistor 11 upon receiving a current Irec (first current) from the detection diode 31 and a bias current I₂₁ from the transistor 21.

The transistor 21 is an example of a second transistor and is a simulated (replica) transistor for the amplification transistor 11. The transistor 21 is connected to the power supply circuit 22 and a bias path connecting the power supply circuit 22 and the amplification transistor 11.

The expression “a transistor B is a simulated transistor for a transistor A” is defined as the transistor B having the same configuration and the same or different size as the transistor A.

The resistor 32 is an example of a first resistor and is disposed in series to the bias path connecting the power supply circuit 22 and the gate of the amplification transistor 11. The resistor 32 may be at least a part of a wiring line forming the above bias path or may be a resistance element.

The detection diode 31 is an example of a first diode and is connected to the above bias path between the resistor 32 and the gate of the amplification transistor 11 and the signal input terminal 110. Specifically, the cathode of the detection diode 31 is connected to the above bias path between the resistor 32 and the gate of the amplification transistor 11, and the anode of the detection diode 31 is connected to a voltage source (not illustrated). Accordingly, the detection diode 31 can output the current Irec corresponding to the power of a radio-frequency signal input from the signal input terminal 110. The above detection in the detection diode 31 is performed by the use of the non-linearity of a diode in which voltage-current characteristics are represented by an exponential function.

The filter 40 is connected between the amplification transistor 11 and the antenna connection terminal 100 and has a predetermined band as a passband. The filter 40 is an optional constituent element in the amplification circuit 1.

<1.3 Comparison between Characteristics of Amplification Circuit according to Embodiment and Amplification Circuit according to Comparative Example>

The amplification characteristics of the amplification circuit 1 according to an embodiment and an amplification circuit according to a comparative example will be compared. An amplification circuit according to a comparative example differs from the amplification circuit 1 according to an embodiment in that it does not include the detection diode 31.

First, the amplification operation of an amplification circuit according to a comparative example will be described.

When the amplification transistor 11 is in an ON state and no radio-frequency signal is input (at the time of no signal or a small signal), the bias voltage vg1r of the transistor 21 is adjusted by the power supply circuit 22 such that the drain current of the transistor 21 becomes a desired value.

At that time, the current Irec from the detection diode 31 does not flow through the above bias path. Accordingly, the bias voltage vg1r is supplied to the gate of the amplification transistor 11.

Subsequently, when a radio-frequency signal is input (at the time of a large signal), the bias voltage vg1r of the transistor 21 and the bias voltage vg1a supplied to the amplification transistor 11 have a constant value.

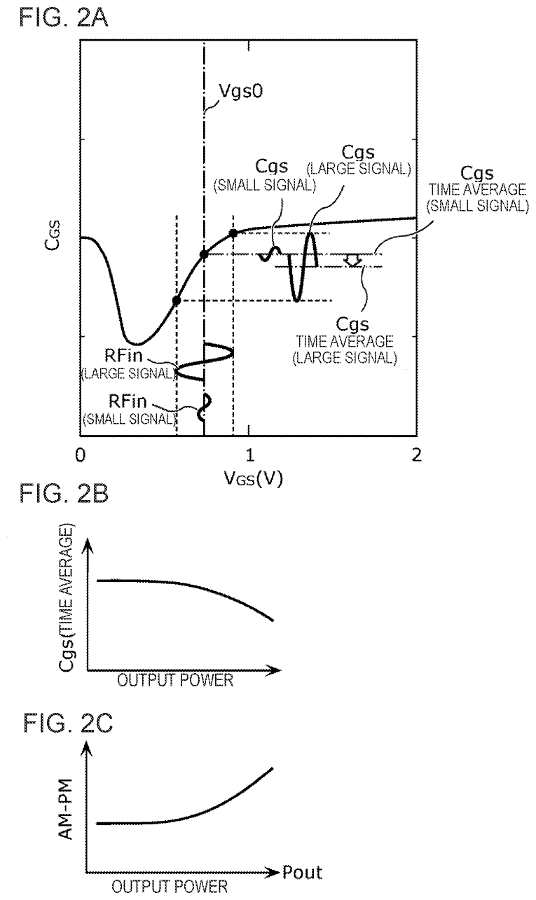

FIG. 2A is a diagram illustrating a relationship between a gate-to-source voltage Vgs and a gate-to-source capacitance Cgs of the amplification transistor 11 according to a comparative example. FIG. 2B is a diagram illustrating a relationship between output power and the gate-to-source capacitance Cgs of an amplification circuit according to a comparative example. FIG. 2C is a diagram illustrating a relationship between output power and amplitude modulation-phase modulation conversion (AM-PM) characteristics of an amplification circuit according to a comparative example.

An example of a cause of the distortion of an output signal of the amplification transistor 11 is the non-linearity of the gate-to-source capacitance Cgs of the amplification transistor 11. The non-linearity of the gate-to-source capacitance Cgs causes the distortion of AM-PM characteristics of an amplification circuit.

As illustrated in FIG. 2A, the gate-to-source capacitance Cgs depends on the gate-to-source voltage Vgs and has a convex curve shape in a region where the gate-to-source voltage Vgs is set. Accordingly, for example, when a large signal RFin is input to the gate (between the gate and the source) in a state in which a bias point is set at Vgs=Vgs0, the time average of the gate-to-source capacitance Cgs becomes smaller than that at the time of the input of a small signal. That is, the time average of the gate-to-source capacitance Cgs decreases with increasing output power Pout of the amplification transistor 11 as illustrated in FIG. 2B. The variation in the gate-to-source capacitance Cgs causes AM-PM characteristics to vary with the output power Pout of the amplification transistor 11 as illustrated in FIG. 2C. That is, the non-linearity of the gate-to-source capacitance Cgs causes the distortion of AM-PM characteristics of an amplification circuit.

Next, the amplification operation of the amplification circuit 1 according to an embodiment will be described.

When the amplification transistor 11 is in the ON state and no radio-frequency signal is input (at the time of no signal or a small signal), the bias voltage vg1r of the transistor 21 is adjusted by the power supply circuit 22 such that the drain current of the transistor 21 becomes a desired value.

At that time, the current Irec from the detection diode 31 flows through the above bias path. Accordingly, the bias voltage vg1a supplied to the gate of the amplification transistor 11 is represented by the following expression 1 where Rc represents the resistance value of the resistor 32.

vg1a=vg1r+Irec×Rc (Expression 1)

Subsequently, when a radio-frequency signal is input (at the time of a large signal), the bias voltage vg1r of the transistor 21 has a constant value. On the other hand, the current Irec of the detection diode 31 increases in accordance with the power of a radio-frequency signal input from the signal input terminal 110. An increase amount Δvg1a of the bias voltage vg1a is represented by the following expression 2 where ΔIrec represents an increase amount of the current Irec.

Δvg1a=ΔIrec×Rc (Expression 2)

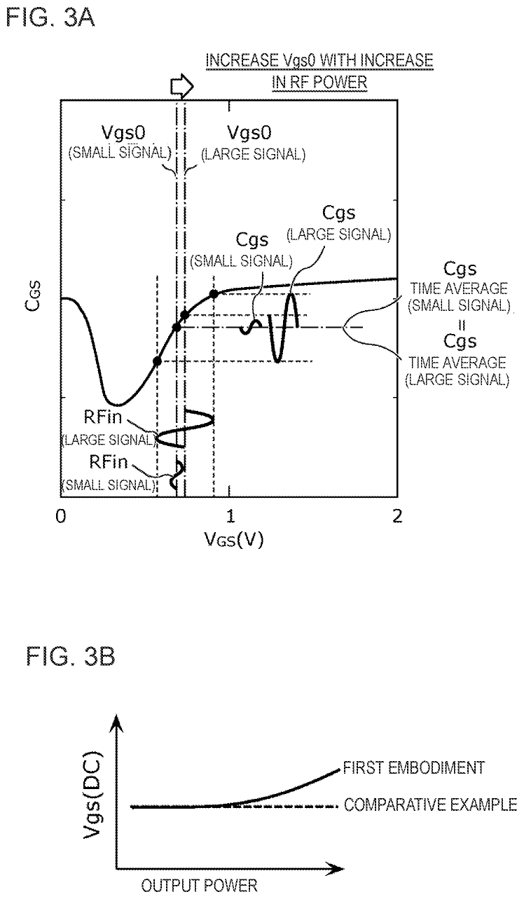

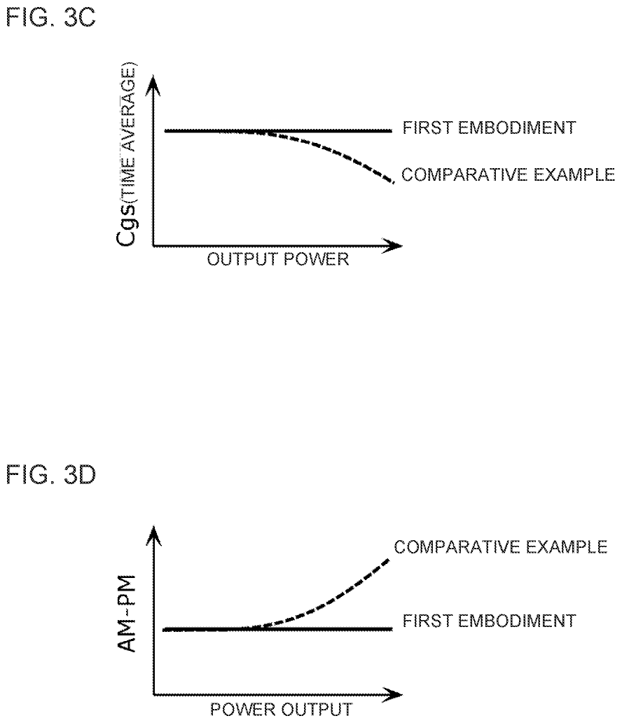

FIG. 3A is a diagram illustrating a relationship between the gate-to-source voltage Vgs and the gate-to-source capacitance Cgs of the amplification transistor 11 according to the first embodiment. FIG. 3B is a diagram illustrating relationships between output power and the gate-to-source voltage Vgs of an amplification circuit according to the first embodiment and an amplification circuit according to a comparative example. FIG. 3C is a diagram illustrating relationships between output power and the gate-to-source capacitance Cgs of an amplification circuit according to the first embodiment and an amplification circuit according to a comparative example. FIG. 3D is a diagram illustrating relationships between output power and AM-PM characteristics of an amplification circuit according to the first embodiment and an amplification circuit according to a comparative example.

For example, when the large signal RFin is input to the gate (between the gate and the source) in the state in which a bias point is set at Vgs=Vgs0 as illustrated in FIG. 3A, the bias voltage vg1a (the gate-to-source voltage Vgs) increases as represented by Expression 2. That is, the bias voltage vg1a (the gate-to-source voltage Vgs) increases with the increasing output power Pout of the amplification transistor 11 as illustrated in FIG. 3B. Accordingly, as illustrated in FIG. 3A, the time average of the gate-to-source capacitance Cgs at the time of a large signal can be made to coincide with the time average of the gate-to-source capacitance Cgs at the time of a small signal. That is, as illustrated in FIG. 3C, the gate-to-source capacitance Cgs can be made to be constant with respect to the variation in the output power Pout of the amplification transistor 11. Accordingly, as illustrated in FIG. 3D, the AM-PM characteristics can be made to be constant with respect to the variation in the output power Pout of the amplification transistor 11. That is, even if the gate-to-source capacitance Cgs has non-linearity, the distortion of AM-PM characteristics of an amplification circuit can be suppressed.

A multi-carrier multi-level modulation technique such as the OFDM has been used in digital communication in recent years. A power amplifier is required to have a high degree of linearity, and AM-PM characteristics are required to be flat irrespective of the power of a radio-frequency signal. The bandwidth of a modulation signal is increasing for the improvement of a communication speed, but a power amplifier is required to be a low-distortion power amplifier irrespective of the bandwidth of the power amplifier.

In the case where an FET is used in an amplification circuit in the related art, a problem arises that the distortion of a power amplifier occurs because of the non-linearity thereof even when a bias voltage is stabilized.

With the amplification circuit 1 according to the present embodiment, the bias voltage vg1a obtained by adding a voltage (Irec×Rc) generated in the resistor 32 to the bias voltage vg1r supplied to the transistor 21 is supplied to the amplification transistor 11. The voltage generated in the resistor 32 is the product of the current Irec corresponding to the power of a radio-frequency signal detected by the detection diode 31 and the resistance value of the resistor 32. In the case where the bias voltage vg1r is controlled to be constant by the power supply circuit 22, the bias voltage vg1a increases in accordance with the power of a radio-frequency signal. The amount of decrease in the time average of the gate-to-source capacitance Cgs of the amplification transistor 11 at the time of the increase in the power of a radio-frequency signal is compensated for by the increase in the bias voltage vg1a. Accordingly, the AM-PM distortion of a radio-frequency signal amplified by the amplification transistor 11 can be suppressed. Since the bias voltage vg1a refers to the bias voltage vg1r, the variation in the bias voltage vg1a due to the temperature variation and the process variation of the amplification transistor 11 can be suppressed.

### <1.4 Circuit Configuration of Amplification Circuit 1B According to First Example>

Next, the circuit configuration of the amplification circuit 1B according to the first example will be described. In the amplification circuit 1 according to the first embodiment, the detection diode 31 is susceptible to a temperature variation and a process variation. In the present example, a configuration will be proposed with which the temperature variation and the process variation of the detection diode 31 are suppressed.

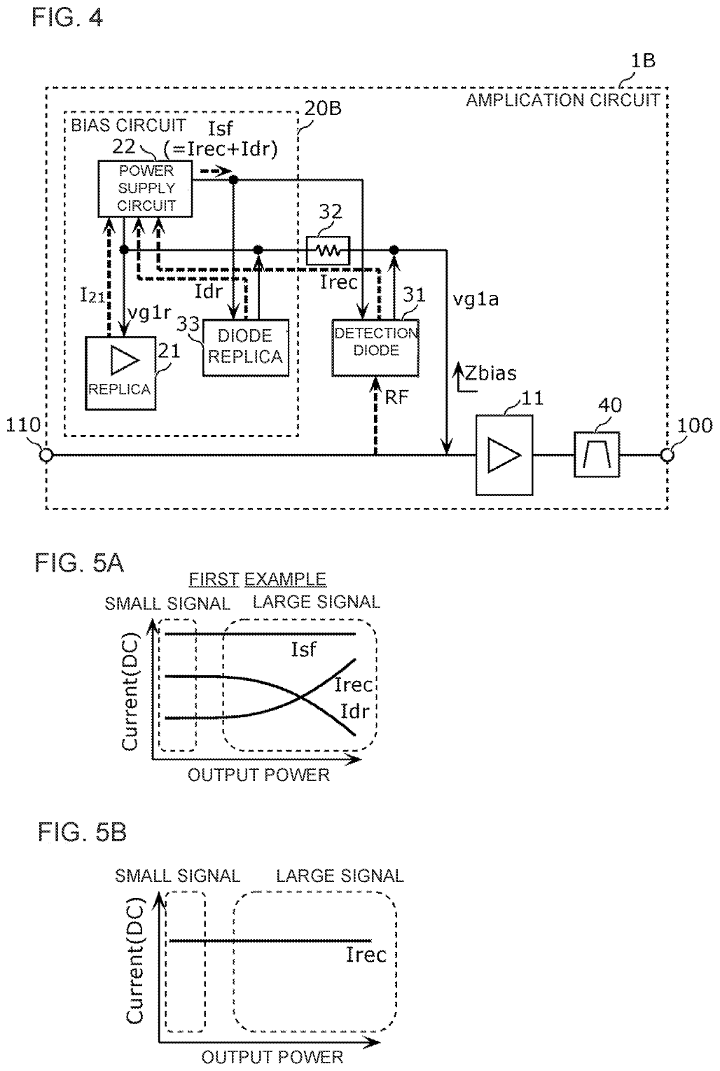

FIG. 4 is a diagram illustrating a circuit configuration of the amplification circuit 1B according to the first embodiment. As illustrated in this drawing, the amplification circuit 1B includes the amplification transistor 11, a bias circuit 20B, the detection diode 31, the resistor 32, the filter 40, the signal input terminal 110, and the antenna connection terminal 100. The amplification circuit 1B according to the present example differs from the amplification circuit 1 according to an embodiment in the configuration of the bias circuit 20B. Hereinafter, the description of similarities in configuration between the amplification circuit 1B according to the present example and the amplification circuit 1 according to the first embodiment will be omitted, and differences in configuration therebetween will be mainly described.

The bias circuit 20B is configured to supply the bias voltage vg1a to the gate of the amplification transistor 11. The bias circuit 20B includes the transistor 21, the power supply circuit 22, and a diode replica 33.

The power supply circuit 22 is configured to supply the constant bias voltage vg1r to the gate of the transistor 21. The power supply circuit 22 is configured to supply the bias voltage vg1a to the gate of the amplification transistor 11 upon receiving the current Irec (first current) from the detection diode 31, a current Idr (second current) from the diode replica 33, and the bias current I₂₁ from the transistor 21.

The diode replica 33 is an example of a second diode and is a simulated (replica) diode for the detection diode 31. The diode replica 33 is connected to a bias path between the resistor 32 and the power supply circuit 22. That is, the detection diode 31 is connected to one of both end portions of the resistor 32 on the amplification transistor 11 side, and the diode replica 33 is connected to the other one of both end portions of the resistor 32 on the power supply circuit 22 side. The resistor 32 has a low resistance value of, for example, several ohms.

With the above configuration, the detection diode 31 detects the power of a radio-frequency signal input to the amplification transistor 11 and outputs the current Irec corresponding to the detected power. The diode replica 33 is separated from a radio-frequency signal.

The expression “a diode B is a simulated diode for a diode A” is defined as the diode B having the same configuration and the same or different size as the diode A.

With the amplification circuit 1B according to the present example, the sum of the current Irec generated in the detection diode 31 and the current Idr generated in the diode replica 33 is supplied to the power supply circuit 22. Accordingly, the variation in the bias voltage vg1a due to the temperature variation and the process variation of the detection diode 31 can be suppressed by controlling the sum in the power supply circuit 22.

Next, the control of the current Irec and the current Idr in the power supply circuit 22 will be described. The power supply circuit 22 according to the present example is controlled such that a sum Isf of the current Irec of the detection diode 31 and the current Idr of the diode replica 33 is maintained constant at a desired value.

FIG. 5A is a diagram illustrating a relationship between output power and a diode current of the amplification circuit 1B according to the first example. FIG. 5B is a diagram illustrating a relationship between output power of an amplification circuit and the current Irec of the detection diode 31 when the current Irec of the detection diode 31 is controlled to be constant without necessarily the use of the diode replica 33.

When no radio-frequency signal is input to the amplification circuit 1B (at the time of no signal or a small signal), the ratio between the current Irec flowing through the detection diode 31 and the current Idr flowing through the diode replica 33 is constant irrespective of a temperature variation and a process variation as illustrated in FIG. 5A (see Expressions 11 and 12 to be described below). Accordingly, Idr=a×Irec can be expressed using a constant a.

Isf=Irec+Idr=(1+a)Irec (Expression 3)

Irec=(1+a)⁻¹Isf (Expression 4)

The current Irec (current at the time of no signal or a small signal) of the detection diode 31 can be made to be constant by performing control to make the sum Isf of currents flowing through the two diodes constant as represented by Expressions 3 and 4. As a result, the temperature variation and the process variation in sensitivity of the detection diode 31 can be suppressed.

When a radio-frequency signal is input to the amplification circuit 1B (at the time of a large signal), the current Irec of the detection diode 31 increases in accordance with the power of the radio-frequency signal as illustrated in FIG. 5A. Since the sum Isf is constant, the current Idr decreases by the amount of increase in the current Irec.

If the diode replica 33 is not present, the detection diode 31 does not function because the current Irec cannot increase even when a radio-frequency signal is input as illustrated in FIG. 5B. That is, the diode replica 33 contributes to the stabilization of the current Irec and the sensitivity of the detection diode 31 and also supports the function of the detection diode 31 at the time of a large signal.

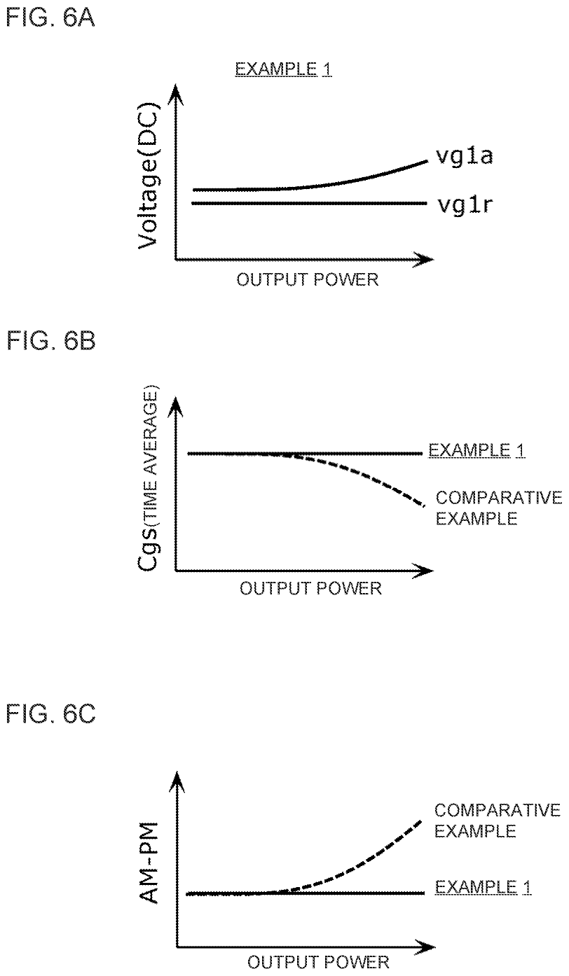

FIG. 6A is a diagram illustrating a relationship between output power and a bias voltage of the amplification circuit 1B according to the first example. FIG. 6B is a diagram illustrating relationships between output power and the gate-to-source capacitance Cgs of an amplification circuit according to the first example and an amplification circuit according to a comparative example. FIG. 6C is a diagram illustrating relationships between output power and AM-PM characteristics of an amplification circuit according to the first example and an amplification circuit according to a comparative example.

The bias voltage vg1a of the amplification transistor 11 increases in accordance with the power of a radio-frequency signal as illustrated in FIG. 6A by performing control to make the current Isf constant. Accordingly, the variation in the time average of the gate-to-source capacitance Cgs is compensated for and the variation in AM-PM characteristics can be suppressed as illustrated in FIGS. 6B and 6C. Since the characteristics of the detection diode 31 and the diode replica 33 shift in the same direction with respect to a temperature variation and a process variation, the variations in the respective currents thereof can be suppressed by controlling the current Isf. As a result, the variation in the characteristics of the detection diode 31 can be suppressed, and the variation in AM-PM characteristics can be suppressed without necessarily the influences of a temperature variation and a process variation.

Since the bias voltage vg1a refers to the bias voltage vg1r like in the amplification circuit 1 according to an embodiment, the variation in the bias voltage vg1a due to the temperature variation and the process variation of the amplification transistor 11 can be suppressed.

Furthermore, since the resistor 32 has a small resistance value of several ohms, an impedance Zbias of the bias circuit 20B viewed from the amplification transistor 11 can be fast and low impedance. As a result, distortion deterioration at the time of amplification of a wide-band modulation signal can be suppressed.

A principle that the influences of a temperature variation and a process variation can be suppressed by controlling the sum Isf will be described.

Diode characteristics are generally approximated by an exponential function, and the relationship between a voltage V of a diode and a current I of the diode is represented by Expression 5.

I≈Is·exp(gV/kT) (Expression 5)

In this expression, q represents an elementary charge, k represents a Boltzmann constant, T represents an absolute temperature, and Is represents a factor of proportionality depending on, for example, a diode size. Simplifying Expression 5 with a voltage as x, a current as y, a=Is, and b=q/k yields Expression 6.

y=a·exp(bx/T) (Expression 6)

Diode characteristics when a temperature varies by only Δt is represented by Expression 7.

y=a·exp(bx/(T+ΔT)) (Expression 7)

Diode characteristics that varies with a process variation between, for example, gate shapes are represented by Expression 8 using a factor m of proportionality.

y=ma·exp(bx/T) (Expression 8)

Next, a behavior when two diodes (e.g., the detection diode 31 and the diode replica 33) are connected in parallel will be described.

Assuming that a voltage applied to the two diodes is x1 (common), the currents of the two diodes are y1 and y2, and x1, y1, and y2 are changed to x1′, y1′, and y2′, respectively under the influences of a temperature variation and a process variation, diode characteristics are represented by the following expressions 9 to 12.

y1=a1·exp(bx1/T) (Expression 9)

y2=a2·exp(bx1/T) (Expression 10)

y1′=ma1·exp(bx1′/(T+ΔT)) (Expression 11)

y2′=ma2·exp(bx1′/(T+ΔT)) (Expression 12)

Using Expressions 9 to 12, the current ratios between the above two diodes, y2/y1 and y2′/y1′, are represented by the following expressions 13 and 14.

y2/y1=a2/a1 (Expression 13)

y2′/y1′=a2/a1 (Expression 14)

From Expression 13 and 14, y2/y1=y2′/y1′ is derived. That is, the current ratio between the above two diodes is constant irrespective of a temperature variation and a process variation.

Next, a temperature variation in sensitivity and a process variation in sensitivity when two diodes (e.g., the detection diode 31 and the diode replica 33) are connected in parallel will be described.

Assuming that the sensitivity of a single diode is z, z is represented by the following expression 15 because z is a second order differential of current-voltage characteristics.

z=d²y/dx²=ab²T²·exp(bx/T) (Expression 15)

In the case where there are influences of a temperature variation and a process variation, sensitivity z′ is represented by the following expression 16.

z′=d²y′/dx′²=mab²(T+ΔT)²·exp(bx′/(T+ΔT)) (Expression 16)

In the case where control processing is performed to avoid a bias current of a diode from being changed under the influences of a temperature variation and a process variation, y=y′ is established and Expression 17 is obtained.

a·exp(bx/T)=ma·exp(bx′/(T+ΔT)) (Expression 17)

Substituting Expression 17 into Expression 16 yields the following expression 18.

z′=zT²(T+ΔT)⁻² (Expression 18)

Expression 18 indicates that, by fixing a bias current flowing through a diode, (1) a process variation in sensitivity can be eliminated in theory and (2) a temperature variation in sensitivity can be markedly suppressed to (T²(T+ΔT)⁻²).

In contrast, fixing a voltage generated in a diode leads to a great variation in sensitivity due to a process variation and a temperature variation.

That is, by performing control processing such that the sum Isf of the current Irec and the current Idr in the power supply circuit 22 is constant (fixed) at a desired value, a temperature variation in sensitivity and a process variation in sensitivity can be suppressed and the AM-PM characteristics of output power of the amplification transistor 11 can be suppressed.

As an aspect of controlling a current flowing through a diode, a current flowing through a diode is caused to have an intended temperature dependence. This can lead to the further suppression of a temperature variation in sensitivity.

This may be applied to control the sum Isf of the current Irec and the current Idr in the power supply circuit 22 such that the sum Isf varies in accordance with at least one of parameters, the temperature of the amplification circuit 1B, a power supply voltage applied to the amplification transistor 11, the output power of the amplification transistor 11, the load impedance of the amplification transistor 11, the frequency of a radio-frequency signal, and a process variation. As a result, the AM-PM characteristics of output power of the amplification transistor 11 can be suppressed.

### <1.5 Circuit Configuration of Amplification Circuit 1C According to Second Example>

Next, the circuit configuration of an amplification circuit 1C according to the second example will be described.

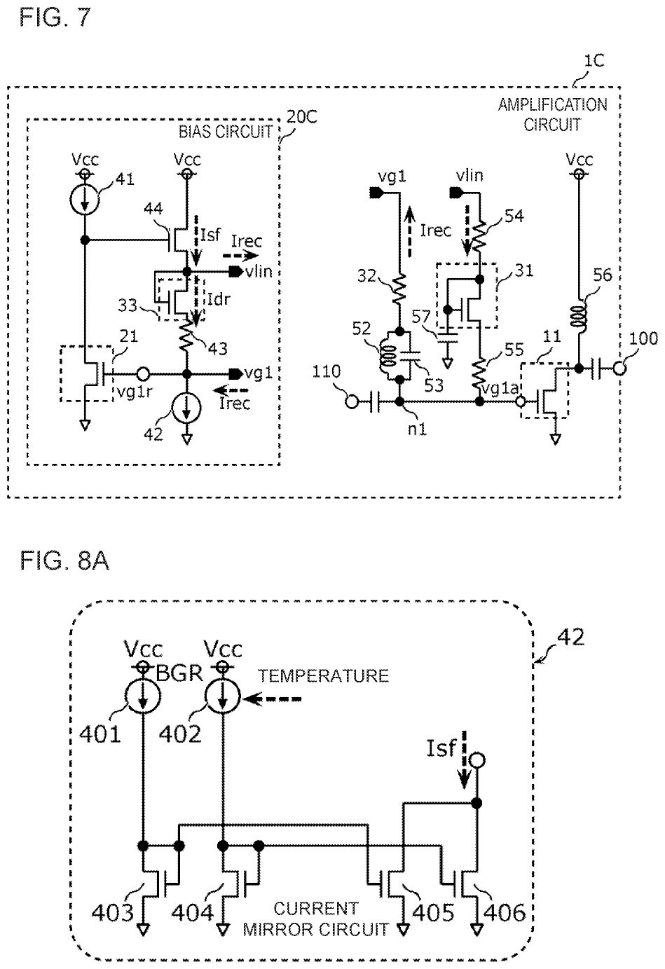

FIG. 7 is a diagram illustrating a circuit configuration of the amplification circuit 1C according to the second example. As illustrated in the drawing, the amplification circuit 1C includes the amplification transistor 11, a bias circuit 20C, the detection diode 31, the resistor 32, resistors 54 and 55, inductors 52 and 56, capacitors 53 and 57, the signal input terminal 110, and the antenna connection terminal 100. The circuit configuration of the amplification circuit 1C according to the present example corresponds to the detailed circuit configuration of the amplification circuit 1B according to the first example. Hereinafter, the description of similarities in configuration between the amplification circuit 1C according to the present example and the amplification circuit 1B according to the first embodiment will be omitted, and differences in configuration therebetween will be mainly described.

The amplification transistor 11 is an example of the first transistor and is an FET connected to the signal input terminal 110. The amplification transistor 11 is, for example, an N-channel FET having a gate connected to the signal input terminal 110, a drain that is connected to the antenna connection terminal 100 and connected to a power supply voltage Vcc via the inductor 56, and a source connected to the ground.

The detection diode 31 is an example of the first diode and has, for example, an anode functioning as the gate and drain of an N-channel FET and a cathode functioning as the source of an N-channel FET. The anode of the detection diode 31 is connected to a terminal vlin via the resistor 54, and the cathode of the detection diode 31 is connected to the signal input terminal 110 and the gate of the amplification transistor 11 via the resistor 55. The anode of the detection diode 31 is also connected to the capacitor 57 and is grounded in radio frequencies. The resistor 55 has, for example, a resistance value of 10Ω or less.

The resistor 32 is an example of the first resistor and has one terminal connected to a node n1 (first node) on a signal path connecting the signal input terminal 110 and the gate of the amplification transistor 11 via the parallel connection circuit of the inductor 52 and the capacitor 53 and the other terminal connected to a terminal vg1. The parallel connection circuit of the inductor 52 and the capacitor 53 and the resistor 32 function as both an RF choke circuit and a bias path.

The bias circuit 20C is configured to supply the bias voltage vg1a to the gate of the amplification transistor 11. The bias circuit 20C includes the transistor 21, a transistor 44, current source circuits 41 and 42, the diode replica 33, and a resistor 43. The transistors 21 and 44 and the current source circuits 41 and 42 form a power supply circuit.

The current source circuit 41 is an example of a first current source circuit, is connected between the power supply voltage Vcc and the drain of the transistor 21, and supplies a constant current to the drain of the transistor 21.

The transistor 44 is an example of a third transistor and has a gate connected to the current source circuit 41 and the drain of the transistor 21, a drain connected to the power supply voltage Vcc, and a source connected to the anode of the detection diode 31 via the terminal vlin and the anode of the diode replica 33.

The current source circuit 42 is an example of a second current source circuit and has one end that is connected to the cathode of the diode replica 33 via the resistor 43 and connected to the other terminal of the resistor 32 via the terminal vg1 and the other end connected to the ground.

By the use of the transistor 44 and the current source circuit 42, the sum Isf of the current Irec flowing through the detection diode 31 and the current Idr flowing through the diode replica 33 becomes constant.

In the amplification circuit 1C, a bias path for supplying the bias voltage vg1a to the amplification transistor 11 includes the gate of the transistor 21, the resistor 32, the node n1, and the gate of the amplification transistor 11.

With the above configuration, the sum Isf is controlled to be maintained constant at a desired value by the bias circuit 20C. Accordingly, the variation in the time average of the gate-to-source capacitance Cgs can be compensated for and the variation in AM-PM characteristics can be suppressed by increasing the bias voltage vg1a of the amplification transistor 11 in accordance with the power of a radio-frequency signal. Since the characteristics of the detection diode 31 and the diode replica 33 shift in the same direction with respect to a temperature variation and a process variation, the respective variations in the currents of the detection diode 31 and the diode replica 33 can be suppressed by controlling the current Isf. As a result, the variation in the characteristics of the detection diode 31 can be suppressed, and the variation in AM-PM characteristics can be suppressed without necessarily the influences of a temperature variation and a process variation. Since the bias voltage vg1a refers to the bias voltage vg1r like in the amplification circuit 1 according to an embodiment, the variation in the bias voltage vg1a due to the temperature variation and the process variation of the amplification transistor 11 can be suppressed. Furthermore, since the resistor 32 has a small resistance value of several ohms, the impedance Zbias of the bias circuit 20C viewed from the amplification transistor 11 can be fast and low impedance. As a result, distortion deterioration at the time of amplification of a wide-band modulation signal can be suppressed.

The control of the sum Isf may be performed such that the sum Isf varies in accordance with at least one of parameters, the temperature of the amplification circuit 1C, a power supply voltage applied to the amplification transistor 11, the output power of the amplification transistor 11, the load impedance of the amplification transistor 11, the frequency of a radio-frequency signal, and a process variation. As a result, the AM-PM characteristics of output power of the amplification transistor 11 can be suppressed.

FIG. 8A is a diagram illustrating an exemplary circuit configuration of the current source circuit 42 according to the second example that changes the sum Isf in accordance with, for example, the temperature of the amplification circuit 1C. As illustrated in this drawing, the current source circuit 42 includes a constant current source 401, a current source 402, transistors 403, 404, 405, and 406.

The constant current source 401 is an example of a first current circuit and is a circuit for generating a constant current. The constant current source 401 is, for example, a band gap reference (BGR) circuit.

The current source 402 is an example of a second current circuit and is a circuit for generating a variation current in accordance with a temperature.

The transistor 403 is an example of a sixth transistor and is, for example, an N-channel FET having a gate and a drain connected to the constant current source 401 and a source connected to the ground.

The transistor 404 is an example of a seventh transistor and is, for example, an N-channel FET having a gate and a drain connected to the current source 402 and a source connected to the ground.

The transistor 405 is an example of an eighth transistor and is, for example, an N-channel FET having a gate connected to the gate of the transistor 403, a drain connected to the cathode of the diode replica 33 and the other terminal of the resistor 32, and a source connected to the ground.

The transistor 406 is an example of a ninth transistor and is, for example, an N-channel FET having a gate connected to the gate of the transistor 404, a drain connected to the cathode of the diode replica 33 and the other terminal of the resistor 32, and a source connected to the ground.

With this configuration, the sum Isf can be changed in accordance with a temperature variation.

FIG. 8B is a diagram illustrating an exemplary circuit configuration of a current source circuit 42A (modification) according to the second example and is a circuit for changing the sum Isf in accordance with, for example, the temperature of the amplification circuit 1C. As illustrated in this drawing, the current source circuit 42A includes the constant current source 401, the transistors 403, 405, and 406 and switches 407 and 408.

The constant current source 401 is an example of the first current circuit and is a circuit for generating a constant current.

The transistor 403 is an example of the sixth transistor and is, for example, an N-channel FET having a gate and a drain connected to the constant current source 401 and a source connected to the ground.

The transistor 405 is an example of the seventh transistor and is, for example, an N-channel FET having a gate connected to the gate of the transistor 403 via the switch 407, a drain connected to the cathode of the diode replica 33 and the other terminal of the resistor 32, and a source connected to the ground.

The transistor 406 is an example of the eighth transistor and is, for example, an N-channel FET having a gate connected to the gate of the transistor 403 via the switch 408, a drain connected to the cathode of the diode replica 33 and the other terminal of the resistor 32, and a source connected to the ground.

With this configuration, the sum Isf can be changed by the switches 407 and 408.

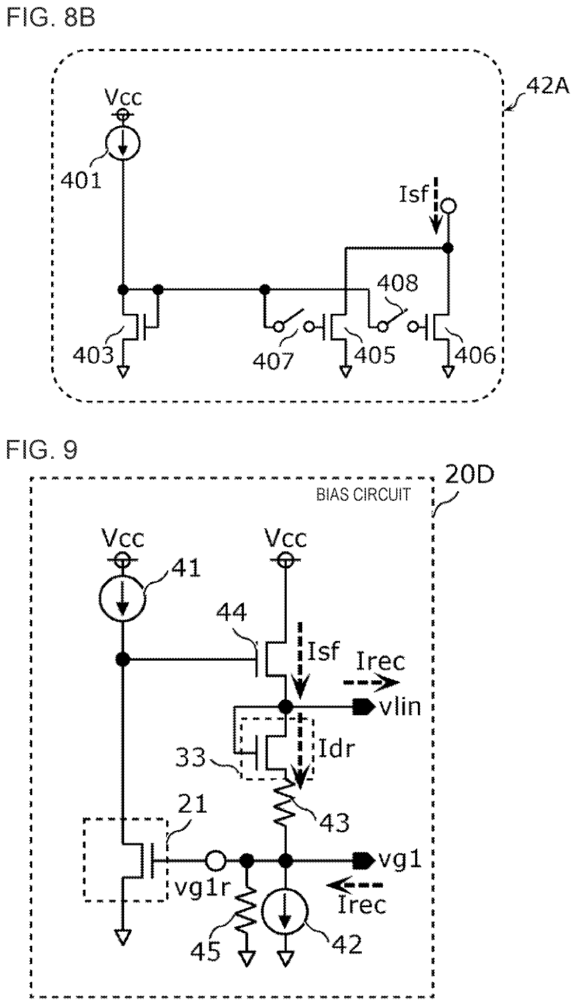

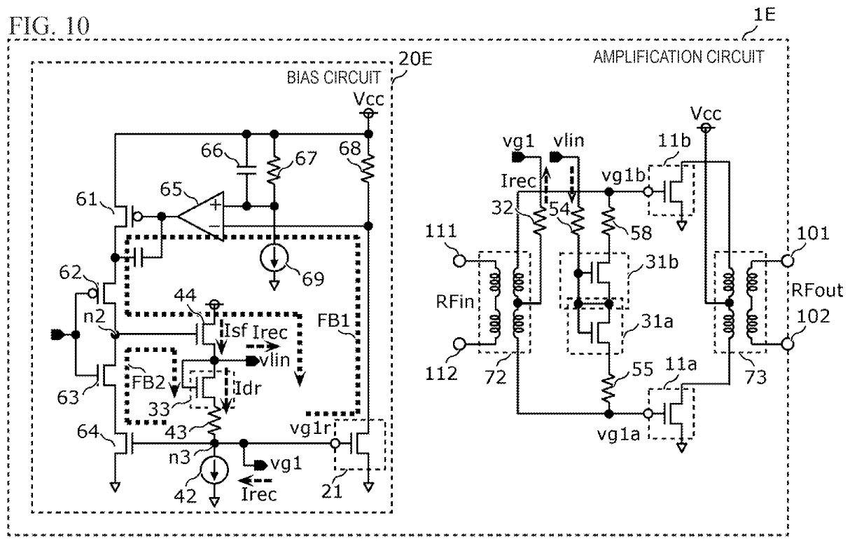

FIG. 9 is a diagram illustrating the circuit configuration of a bias circuit 20D (modification) according to the second example. The bias circuit 20D according to the present modification includes the transistors 21 and 44, the current source circuits 41 and 42, the diode replica 33, and the resistor 43, and a resistor 45. The bias circuit 20D according to the present modification differs from the bias circuit 20C according to the second example only in that the resistor 45 is added. Hereinafter, the description of similarities in configuration between the bias circuit 20D according to the present modification and the bias circuit 20C according to the second example will be omitted, and differences in configuration therebetween will be mainly described.

The resistor 45 is connected between a node on a bias path connecting the terminal vg1 and the gate of the transistor 21 and the ground. That is, the resistor 45 is connected in parallel to the current source circuit 42.

Even when the bias circuit 20D according to the present modification is applied to the amplification circuit 1C according to the second example, the same effect as that obtained when the bias circuit 20C is applied to the amplification circuit 1C can be obtained.

### <1.6 Circuit Configuration of Amplification Circuit 1E According to Third Example>

FIG. 10 is a diagram illustrating the circuit configuration of an amplification circuit 1E according to the third example. As illustrated in this drawing, the amplification circuit 1E includes amplification transistors 11a and 11b, a bias circuit 20E, detection diodes 31a and 31b, resistors 32, 54, and 55, a resistor 58, transformers 72 and 73, signal input terminals 111 and 112, and antenna connection terminals 101 and 102. The circuit configuration of the amplification circuit 1E according to the present example corresponds to the detailed circuit configuration of the amplification circuit 1B according to the first example. Hereinafter, the description of similarities in configuration between the amplification circuit 1E according to the present example and the amplification circuit 1B according to the first example will be omitted, and differences in configuration therebetween will be mainly described.

Each of the signal input terminals 111 and 112 is an example of the first radio-frequency input terminal, and differential (balanced) signals that has been subjected to phase inversion are input to the signal input terminals 111 and 112.

The transformer 72 is an example of a first transformer and includes a primary side coil and a secondary side coil. One end of the primary side coil of the transformer 72 is connected to the signal input terminal 111, and the other end of the primary side coil of the transformer 72 is connected to the signal input terminal 112. The other end of the primary side coil of the transformer 72 may be connected to the ground, and an unbalanced signal may be input from the signal input terminal 111.

The amplification transistor 11a is an example of the first transistor and is an FET connected to the signal input terminal 111 or 112 via the transformer 72. The amplification transistor 11a is, for example, an N-channel FET having a gate connected to one end of the secondary side coil of the transformer 72, a drain connected to the antenna connection terminal 102 via the transformer 73, and a source connected to the ground.

The amplification transistor 11b is an example of a tenth transistor and is an FET connected to the signal input terminal 111 or 112 via the transformer 72. The amplification transistor 11b is, for example, an N-channel FET having a gate connected to the other end of the secondary side coil of the transformer 72, a drain connected to the antenna connection terminal 101 via the transformer 73, and a source connected to the ground.

The detection diode 31a is an example of the first diode and has, for example, an anode functioning as the gate and drain of an N-channel FET and a cathode functioning as the source of an N-channel FET. The anode of the detection diode 31a is connected to the terminal vlin via the resistor 54, and the cathode thereof is connected a bias path between the gate of the amplification transistor 11a and the secondary side coil of the transformer 72 via the resistor 55.

The detection diode 31b is an example of a third diode and has, for example, an anode functioning as the gate and drain of an N-channel FET and a cathode functioning as the source of an N-channel FET. The anode of the detection diode 31b is connected to the terminal vlin via the resistor 54, and the cathode thereof is connected to a bias path between the gate of the amplification transistor 11b and the secondary side coil of the transformer 72 via the resistor 58. The anodes of the detection diodes 31a and 31b are virtually grounded by being connected in common.

A bias path includes the gate of the transistor 21, the terminal vg1, the resistor 32, the secondary side coil of the transformer 72, the gate of the amplification transistor 11a, and the gate of the amplification transistor 11b.

The detection diodes 31a and 31b can therefore be separated from the amplification transistors 11a and 11b in radio frequencies without necessarily the use of the parallel connection circuit of the inductor 52 and the capacitor 53 and the capacitor 57 which are needed in the amplification circuit 1C according to the second example.

The resistor 32 is an example of the first resistor and has one terminal connected to the secondary side coil (the midpoint of the secondary side coil) of the transformer 72 and the other terminal connected to the terminal vg1.

The bias circuit 20E is configured to supply the bias voltages vg1r, vg1a, and a bias voltage vg1b to the gates of the amplification transistors 21, 11a, and 11b, respectively. More specifically, the bias circuit 20E detects the drain current and gate voltage of the transistor 21 and applies the bias voltages vg1r, vg1a, vg1b to the amplification transistors 21, 11a, and 11b, respectively to suppress the variation in the gate voltage and the variation in the drain current.

The bias circuit 20E includes the transistors 21 and 44, transistors 61 62, 63, and 64, the current source circuit 42, the diode replica 33, a comparator 65, the resistor 43, resistors 67 and 68, a capacitor 66, and a current source 69. The transistors 21, 44, and 61 and the current source circuit 42 form a power supply circuit.

The cathode of the diode replica 33 and the gate of the transistor 21 are connected to the other terminal of the resistor 32 via the terminal vg1.

The comparator 65 has, for example, a positive side input terminal, a negative side input terminal, and an output terminal and outputs a signal corresponding to a difference between a voltage value applied to the positive side input terminal and a voltage value applied to the negative side input terminal from the output terminal.

The resistor 67 and the current source 69 is a circuit for generating a reference value that is a voltage value applied to the positive side input terminal of the comparator 65. One end of the resistor 67 is connected to the power supply voltage Vcc, and the other end thereof is connected to one end of the current source 69 and the positive side input terminal of the comparator 65. One end of the current source 69 is connected to the other end of the resistor 67 and the positive side input terminal of the comparator 65, and the other end of the current source 69 is connected to the ground. By setting a current value that the current source 69 flows and the resistance value of the resistor 67 as appropriate, a reference value applied to the positive side input terminal of the comparator 65 can be generated. By using the current source 69 for the generation of a reference value, a stable reference value can be generated.

The comparator 65, the resistor 67, and the current source 69 form an error amplification circuit.

The resistor 68 is an example of a first bias detection circuit and detects the drain current of the transistor 21. One end of the resistor 68 is connected to the drain of the transistor 21 and the negative side input terminal of the comparator 65, and the other end thereof is connected to the power supply voltage Vcc.

The transistors 61, 62, 63, and 44, nodes n2 and n3, and the current source circuit 42 form a bias output buffer circuit.

The transistor 61 is an example of a fourth transistor and is a P-channel FET. The transistor 61 is connected between the output terminal of the comparator 65 and the node n2. Specifically, the gate of the transistor 61 is connected to the output terminal of the comparator 65, the drain of the transistor 61 is connected to the node n2 (second node) via the transistor 62, and the source of the transistor 61 is connected to the power supply voltage Vcc.

The transistor 44 is an example of a third transistor and has a gate connected to the node n2, a drain connected to the power supply voltage Vcc, and a source that is connected to the anodes of the detection diodes 31a and 31b via the terminal vlin and connected to the anode of the diode replica 33.

The transistor 64 forms a second bias detection circuit and is, for example, an N-channel FET. The transistor 64 is connected between the node n2 and the node n3 (third node). Specifically, the gate of the transistor 64 is connected to the node n3, the drain of the transistor 64 is connected to the node n2 via the transistor 63, and the source of the transistor 64 is connected to the ground.

The transistor 62 is, for example, a P-channel FET. The gate of the transistor 62 is connected to the gate of the transistor 63, the drain of the transistor 62 is connected to the node n2, and the source of the transistor 62 is connected to the drain of the transistor 61.

The transistor 63 is, for example, an N-channel FET. The drain of the transistor 63 is connected to the node n2, and the source of the transistor 63 is connected to the drain of the transistor 64. A voltage for determining the operating point of the transistor 62 is input to the gate of the transistor 62, and a voltage determining the operating point of the transistor 63 is input to the gate of the transistor 63.

The node n2 is connected between the transistor 61 and the node n3 and between the transistors 61 and 64. The node n3 is connected to the cathode of the diode replica 33 and the gate of the transistor 21. The current source circuit 42 is connected between the node n3 and the ground.

The gate of the transistor 21 is connected to the gate of the amplification transistor 11a and the gate of the amplification transistor 11b via the terminal vg1, the resistor 32, and the secondary side coil of the transformer 72.

A feedback circuit formed by the first bias detection circuit, the error amplification circuit, and the transistor 61 forms a feedback path FB1. The feedback path FB1 provided with the error amplification circuit having a high gain and the transistor 61 has a high loop gain but has a narrow loop band instead. Accordingly, the feedback circuit formed by the first bias detection circuit, the error amplification circuit, and the transistor 61 is a high-accuracy and low-speed feedback circuit with a narrow loop band and a high loop gain.

A feedback circuit formed by the second bias detection circuit forms a feedback path FB2. The feedback path FB2 provided with only the transistor 64 has a low loop gain but has a wide loop band instead. The transistor 44 does not have an amplification action because it has a source that is an output to the gate of the transistor 21. Accordingly, the feedback circuit formed by the second bias detection circuit is a low-accuracy and high-speed feedback circuit with a low loop gain and a wide loop band.

In the case where the gate voltage of the transistor 21 varies because of, for example, a disturbance or a temperature change, the low-speed feedback circuit forming the feedback path FB1 and the high-speed feedback circuit forming the feedback path FB2 operate to suppress the variation. That is, the above low-speed feedback circuit and the above high-speed feedback circuit suppress the increase in the gate voltage of the transistor 21.

With the above configuration, the sum Isf is controlled to be maintained constant at a desired value by the bias circuit 20E. Accordingly, the variation in the time average of the gate-to-source capacitance Cgs is compensated for and the variation in AM-PM characteristics can be suppressed by increasing the bias voltage vg1a of the amplification transistor 11a and the bias voltage vg1b of the amplification transistor 11b in accordance with the power of a radio-frequency signal. Since the characteristics of the detection diodes 31a and 31b and the diode replica 33 shift in the same direction with respect to a temperature variation and a process variation, the respective variations in the currents of the detection diodes 31a and 31b and the diode replica 33 can be suppressed by controlling the current Isf. As a result, the variation in the characteristics of the detection diodes 31a and 31b can be suppressed, and the variation in AM-PM characteristics can be suppressed without necessarily the influences of a temperature variation and a process variation. Since the bias voltages vg1a and vg1b refer to the bias voltage vg1r like in the amplification circuit 1 according to an embodiment, the variation in the bias voltage vg1a due to the temperature variations and the process variations of the amplification transistors 11a and 11b can be suppressed. Furthermore, since the resistor 32 has a small resistance value of several ohms, the impedance Zbias of the bias circuit 20E viewed from the amplification transistors 11a and 11b can be fast and low impedance. As a result, distortion deterioration at the time of amplification of a wide-band modulation signal can be suppressed.

The control of the sum Isf may be performed such that the sum Isf varies in accordance with at least one of parameters, the temperature of the amplification circuit 1E, power supply voltages applied to the amplification transistors 11a and 11b, the output power of the amplification transistors 11a and 11b, the load impedances of the amplification transistors 11a and 11b, the frequency of a radio-frequency signal, and a process variation. As a result, the AM-PM characteristics of output power of the amplification transistors 11a and 11b can be suppressed.

For example, in the amplification circuit 1E, the resistance value of at least one of the resistor 32 or 43 may vary with temperature (may have temperature dependence). In this case, the variations in the characteristics of the amplification transistors 11a and 11b due to the temperature dependence of the detection diodes 31a and 31b can be canceled out and good linearity can be achieved independent of temperature. To change the resistance values of the resistors 32 and 43, a variable resistor may be used or a switch may switch between connections between a plurality of resistance elements. That is, instead of the resistor 43, a first variable resistance circuit may be connected between the cathode of the diode replica 33 and the node n3. A variable resistance circuit having a variable resistance value may be disposed instead of the resistor 32.

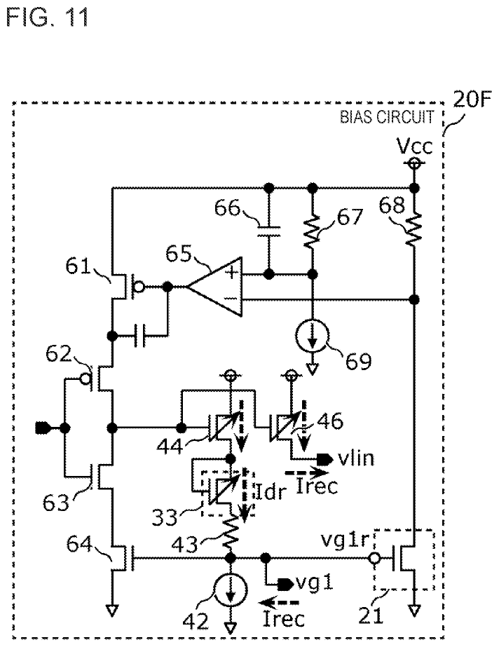

FIG. 11 is a diagram illustrating the circuit configuration of a bias circuit 20F (modification) according to the third example. The bias circuit 20F according to the present modification includes the transistors 21, 44, 61, 62, 63, and 64, a transistor 46, the current source circuit 42, the diode replica 33, the comparator 65, the resistors 43, 67, and 68, the capacitor 66, and the current source 69. The bias circuit 20F according to the present modification differs from the bias circuit 20E according to the third example in that the parameters of the transistor 44 and the diode replica 33 are variable and the transistor 46 having a variable parameter is added. Hereinafter, the description of similarities in configuration between the bias circuit 20F according to the present modification and the bias circuit 20E according to the third example will be omitted, and differences in configuration therebetween will be mainly described.

The parameters of the transistors 44 and 46 and the diode replica 33 can be changed in accordance with a monitor value such as a temperature, the power supply voltage Vcc, output power, a load impedance, a frequency, or a process variation.

The transistor 46 is an example of a fifth transistor, and has a gate connected to the node n2, a drain connected to the power supply voltage Vcc, and a source connected to the Terminal vlin.

Accordingly, the ratio between the current Idr generated in the diode replica 33 and the current Irec generated in the detection diode 31 can be changed, and the sensitivity of the detection diode 31 can be adjusted. For example, the sensitivity of the detection diode 31 can be set to zero by turning off the transistor 46.

The bias circuit 20F can control the sum Isf such that the sum Isf varies in accordance with at least one of parameters, the temperature of the amplification circuit 1E, power supply voltages applied to the amplification transistors 11a and 11b, the output power of the amplification transistors 11a and 11b, the load impedances of the amplification transistors 11a and 11b, the frequency of a radio-frequency signal, and a process variation.

In the amplification circuit 1E according to the present example, the bias circuit 20C according to the second example may be applied instead of the bias circuit 20E.

In the amplification circuit 1C according to the second example, the bias circuit 20E according to the third example may be applied instead of the bias circuit 20C.

### <1.7 Effects, Etc.>

As described above, the amplification circuit 1 according to the present embodiment includes the amplification transistor 11 connected to the signal input terminal 110, the power supply circuit 22 configured to supply the bias voltage vg1a to the amplification transistor 11, the resistor 32 disposed in series to a bias path connecting the power supply circuit 22 and the amplification transistor 11, the transistor 21 that is connected to the bias path and the power supply circuit 22 and that is a simulated transistor for the amplification transistor 11, and the detection diode 31 connected to the signal input terminal 110 and the bias path between the resistor 32 and a gate of the amplification transistor 11.

With this configuration, the bias voltage vg1a obtained by adding a voltage (Irec×Rc) generated in the resistor 32 to the bias voltage vg1r supplied to the transistor 21 is supplied to the amplification transistor 11. In the case where the bias voltage vg1r is controlled to be constant by the power supply circuit 22, the bias voltage vg1a increases in accordance with the power of a radio-frequency signal. The amount of decrease in the time average of the gate-to-source capacitance Cgs of the amplification transistor 11 at the time of the increase in the power of a radio-frequency signal is compensated for by the increase in the bias voltage vg1a. Accordingly, the AM-PM distortion of a radio-frequency signal amplified by the amplification transistor 11 can be suppressed. Since the bias voltage vg1a refers to the bias voltage vg1r, the variation in the bias voltage vg1a due to the temperature variation and the process variation of the amplification transistor 11 can be suppressed.

For example, the amplification circuit 1B according to the first example may further include the diode replica 33, and the diode replica 33 may be connected to the bias path between the resistor 32 and the power supply circuit 22.

With this configuration, the sum of the current Irec generated in the detection diode 31 and the current Idr generated in the diode replica 33 is supplied to the power supply circuit 22. Accordingly, the variation in the bias voltage vg1a due to the temperature variation and the process variation of the detection diode 31 can be suppressed by controlling the sum in the power supply circuit 22.

In the amplification circuits 1B, 1C, and 1E according to the first embodiment, for example, the power supply circuit 22 may be configured such that the sum Isf of the current Irec flowing through the detection diode 31 and the current Idr flowing through the diode replica 33 becomes a constant value.

With this configuration, the temperature variation and the process variations in sensitivity of the detection diode 31 can be suppressed and the AM-PM characteristics of output power of the amplification transistor 11 can be suppressed by performing control processing such that the sum Isf is constant (fixed).

In the amplification circuits 1B, 1C, and 1E, for example, the power supply circuit 22 may be configured such that the sum Isf varies in accordance with at least one of parameters, a temperature of the amplification circuit, a power supply voltage applied to the amplification transistor 11, output power of the amplification transistor 11, a load impedance of the amplification transistor 11, a frequency of a radio-frequency signal, and a process variation.

With this configuration, the AM-PM characteristics of output power of the amplification transistor 11 can be suppressed.

In the amplification circuit 1C according to the second example, for example, a cathode of the detection diode 31 may be connected to the gate of the amplification transistor 11, a first terminal of the resistor 32 may be connected to the node n1 on a signal path connecting the signal input terminal 110 and the gate of the amplification transistor 11, a second terminal of the resistor 32 may be connected to a cathode of the diode replica 33 and a gate of the transistor 21, the bias path may include the gate of the transistor 21, the resistor 32, the node n1, and the gate of the amplification transistor 11, and the power supply circuit 22 may include the transistor 44 having a gate, a drain, and a source, the gate being connected to the current source circuit 41 and a drain or a source of the transistor 21, one of the drain and the source being connected to the power supply voltage Vcc, the other one of the drain and the source being connected to an anode of the detection diode 31 and an anode of the diode replica 33, and the current source circuit 42 connected between a ground and each of a cathode of the diode replica 33 and the second terminal of the resistor 32.

With this configuration, the sum Isf is controlled to be maintained constant at a desired value by the bias circuit 20C. Accordingly, the variation in the time average of the gate-to-source capacitance Cgs can be compensated for and the variation in AM-PM characteristics can be suppressed by increasing the bias voltage vg1a of the amplification transistor 11 in accordance with the power of a radio-frequency signal. Since the characteristics of the detection diode 31 and the diode replica 33 shift in the same direction with respect to a temperature variation and a process variation, the respective variations in the currents of the detection diode 31 and the diode replica 33 can be suppressed by controlling the current Isf. As a result, the variation in the characteristics of the detection diode 31 can be suppressed, and the variation in AM-PM characteristics can be suppressed without necessarily the influences of a temperature variation and a process variation. Since the bias voltage vg1a refers to the bias voltage vg1r like in the amplification circuit 1 according to an embodiment, the variation in the bias voltage vg1a due to the temperature variation and the process variation of the amplification transistor 11 can be suppressed.

In the amplification circuit 1E according to the third example, for example, a cathode of the detection diode 31a may be connected to the gate of the amplification transistor 11a, a first terminal of the resistor 32 may be connected to a node (a midpoint of the secondary side coil of the transformer 72 in FIG. 10: a first node) on a signal path connecting the signal input terminal 111 or 112 and the gate of the amplification transistor 11a, a second terminal of the resistor 32 may be connected to a cathode of the diode replica 33 and a gate of the transistor 21, the bias path may include the gate of the transistor 21, the terminal vg1, the resistor 32, and the gate of the amplification transistor 11a, the amplification circuit 1E may further include a first bias detection circuit, an error amplification circuit, and a second bias detection circuit, the error amplification circuit may include the comparator 65, the power supply circuit may include the transistor 44, the transistor 61, the node n2, the node n3, and the current source circuit 42, the transistor 44 may have a gate, a drain, and a source, the gate being connected to the node n2, one of the drain and the source being connected to the power supply voltage Vcc, the other one of the drain and the source being connected to an anode of the detection diode 31a and an anode of the diode replica 33, the transistor 61 may be connected between the comparator 65 and the node n2, the node n2 may be connected between the transistor 61 and the node n3 and between the transistor 61 and the second bias detection circuit, the node n3 may be connected to a cathode of the diode replica 33 and the gate of the transistor 21, the current source circuit 42 may be connected between the node n3 and a ground, the first bias detection circuit may be connected between a drain or a source of the transistor 21 and the comparator 65, the second bias detection circuit may be connected between the node n2 and the node n3, and the gate of the transistor 21 may be connected to a gate of the amplification transistor 11a.

With this configuration, in the case where the gate voltage of the transistor 21 varies because of, for example, a disturbance or a temperature change, the low-speed feedback circuit forming the feedback path FB1 and the high-speed feedback circuit forming the feedback path FB2 operate to suppress the variation. Accordingly, the above low-speed feedback circuit and the above high-speed feedback circuit can suppress the increase in the gate voltage of the transistor 21.

For example, the amplification circuit 1E may further include a first variable resistance circuit connected between the diode replica 33 and the node n3.

With this configuration, the variations in the characteristics of the amplification transistors 11a and 11b due to the temperature dependence of the detection diodes 31a and 31b can be canceled out and good linearity can be achieved independent of temperature.

For example, the amplification circuit 1E may further include the transistor 46 having a gate, a drain, and a source, the gate being connected to the node n2, one of the drain and the source being connected to the power supply voltage Vcc, the other one of the drain and the source being connected to the anode of the detection diode 31a.

With this configuration, the ratio between the current Idr generated in the diode replica 33 and the current Irec generated in the detection diode 31 can be changed, and the sensitivity of the detection diode 31 can be adjusted.

In the amplification circuits 1C and 1E, for example, the current source circuit 42 may include the constant current source 401 configured to generate a constant current, the current source 402 configured to generate a variation current in accordance with a temperature, the transistor 403 having a gate, a drain, and a source, the gate and one of the drain and the source being connected to the constant current source 401, the transistor 404 having a gate, a drain, and a source, the gate and the other one of the drain and the source being connected to the transistor 402, the transistor 405 having a gate, a drain, and a source, the gate being connected to the gate of the transistor 403, one of the drain and the source being connected to the cathode of the diode replica 33 and the second terminal of the resistor 32, the other one of the drain and the source being connected to a ground, and the transistor 406 having a gate, a drain, and a source, the gate being connected to the gate of the transistor 404, one of the drain and the source being connected to the cathode of the diode replica 33 and the second terminal of the resistor 32, the other one of the drain and the source being connected to a ground.

With this configuration, the sum Isf can be changed in accordance with a temperature variation.

In the amplification circuits 1C and 1E, for example, the current source circuit 42A may include the constant current source 401 configured to generate a constant current, the transistor 403 having a gate, a drain, and a source, the gate and one of the drain and the source being connected to the constant current source 401, the transistor 405 having a gate, a drain, and a source, the gate being connected to the gate of the transistor 403 via the switch 407, one of the drain and the source being connected to the cathode of the diode replica 33 and the second terminal of the resistor 32, the other one of the drain and the source being connected to a ground, and the transistor 406 having a gate, a drain, and a source, the gate being connected to the gate of the transistor 403 via the switch 408, one of the drain and the source being connected to the cathode of the diode replica 33 and the second terminal of the resistor 32, the other one of the drain and the source being connected to a ground.

With this configuration, the sum Isf can be changed by the switches 407 and 408.

For example, the amplification circuit 1E further includes the amplification transistor 11b, the detection diode 31b, and the transformer 72 including a primary side coil and a secondary side coil. At least one of a first end or a second end of the primary side coil is connected to the signal input terminal 111 or 112. A first end of the secondary side coil is connected to the gate of the amplification transistor 11a. A second end of the secondary side coil is connected to a gate of the amplification transistor lib. A first terminal of the resistor 32 is connected to a second node of the secondary side coil, and a second terminal of the resistor 32 is connected to the power supply circuit. The bias path includes the power supply circuit, the resistor 32, the secondary side coil, the gate of the amplification transistor 11a, and the gate of the amplification transistor 11b. A cathode of the detection diode 31a is connected to the bias path between the gate of the amplification transistor 11a and the secondary side coil. A cathode of the detection diode 31b is connected to the bias path between the gate of the amplification transistor 11b and the secondary side coil. An anode of the detection diode 31a is connected to an anode of the detection diode 31b.

With this configuration, the variation in AM-PM characteristics can be suppressed in the amplification circuit 1E that is a differential amplification circuit.

In the amplification circuit 1E, for example, the resistor 32 may have a variable resistance value.

With this configuration, for example, the variations in the characteristics of the amplification transistors 11a and 11b due to the temperature dependence of the detection diodes 31a and 31b can be canceled out and good linearity can be achieved independent of temperature.

The communication device 4 according to the present embodiment includes the RFIC 3 configured to process a radio-frequency signal and the amplification circuit 1 configured to transmit the radio-frequency signal between the RFIC 3 and the antenna 2.

With this configuration, the effect of the amplification circuit 1 can be achieved in the communication device 4.

### Second Embodiment

### <2.1 Circuit Configuration of Amplification Circuit 1A>

The circuit configuration of the amplification circuit 1A according to the second embodiment will be described.

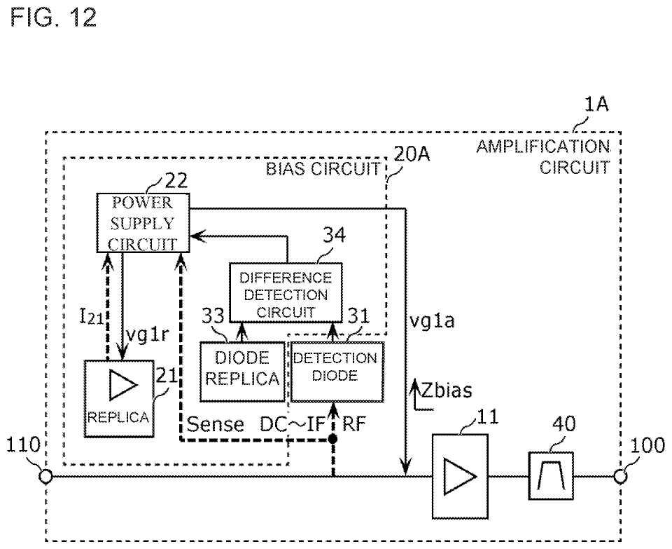

FIG. 12 is a diagram illustrating the circuit configuration of the amplification circuit 1A according to the second embodiment. In this drawing, the amplification circuit 1A includes the amplification transistor 11, a bias circuit 20A, the detection diode 31, the filter 40, the signal input terminal 110, and the antenna connection terminal 100. The amplification circuit 1A according to the present embodiment differs from the amplification circuit 1B according to the first example of the first embodiment in the configuration of the bias circuit 20A. Hereinafter, the description of similarities in configuration between the amplification circuit 1A according to the present embodiment and the amplification circuit 1B according to the first example will be omitted, and differences in configuration therebetween will be mainly described.

The bias circuit 20A is configured to supply the bias voltage vg1a to the gate of the amplification transistor 11. The bias circuit 20A includes the transistor 21, the power supply circuit 22, the diode replica 33, and a difference detection circuit 34.

The power supply circuit 22 is configured to supply the constant bias voltage vg1r to the gate of the transistor 21. The power supply circuit 22 is also configured to supply the bias voltage vg1a that is the sum of the bias voltage vg1r and a voltage corresponding to a differential current detected by the difference detection circuit 34.

The detection diode 31 is an example of the first diode and is connected between the difference detection circuit 34 and the signal input terminal 110. Specifically, one end of the detection diode 31 is connected to a node on a path connecting the signal input terminal 110 and the gate of the amplification transistor 11, and the other end of the detection diode 31 is connected to the difference detection circuit 34. The detection diode 31 can therefore output a current corresponding to the power of a radio-frequency signal input from the signal input terminal 110 to the difference detection circuit 34.

The diode replica 33 is an example of the second diode, and is a simulated (replica) diode for the detection diode 31. The diode replica 33 is connected to the difference detection circuit 34.

The difference detection circuit 34 is connected between the power supply circuit 22 and each of the detection diode 31 and the diode replica 33 and is configured to output to the power supply circuit 22 a differential current between the current Irec flowing through the detection diode 31 and the current Idr flowing through the diode replica 33.

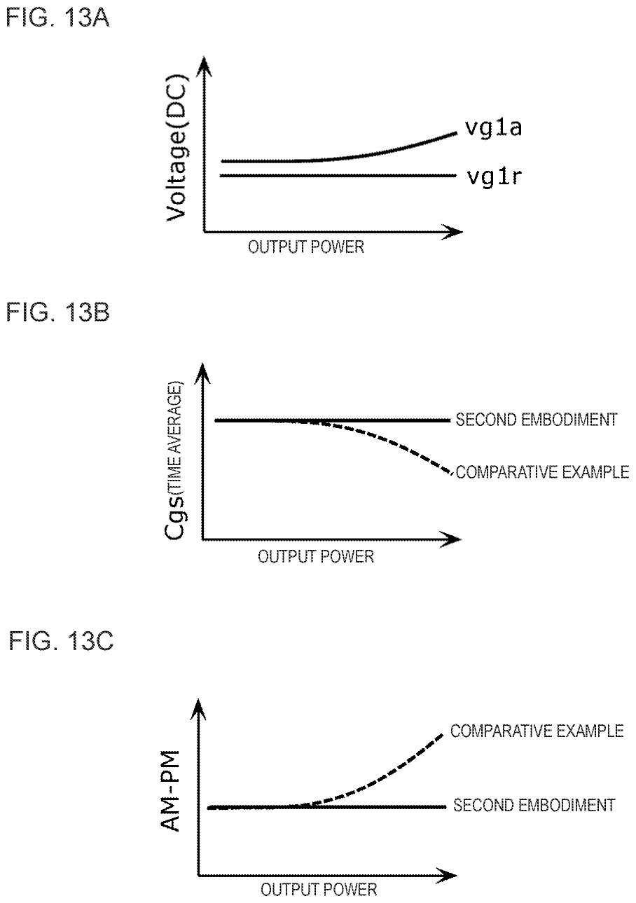

FIG. 13A is a diagram illustrating a relationship between output power and a bias voltage of the amplification circuit 1A according to the second embodiment. FIG. 13B is a diagram illustrating relationships between output power and a gate-to-source capacitance of an amplification circuit according to the second embodiment and an amplification circuit according to a comparative example. FIG. 13C is a diagram illustrating relationships between output power and an amplitude modulation-phase modulation conversion (AM-PM) characteristics of an amplification circuit according to the second embodiment and an amplification circuit according to a comparative example.

In the amplification circuit 1A according to the present embodiment, the bias voltage vg1a obtained by adding a voltage corresponding to a differential current output from the difference detection circuit 34 to the bias voltage vg1r supplied to the transistor 21 is supplied to the amplification transistor 11 as illustrated in FIG. 13A. Since the characteristics of the detection diode 31 and the diode replica 33 shift in the same direction with respect to a temperature variation and a process variation, the variation in a differential current can be suppressed. A voltage corresponding to the power of a radio-frequency signal detected by the detection diode 31 is generated. Accordingly, the decrease in the time average of the gate-to-source capacitance Cgs of the amplification transistor 11 at the time of the increase in the power of a radio-frequency signal is compensated for by the increase in the bias voltage vg1a (see FIG. 13B). As a result, the variation in the characteristics of the detection diode 31 can be suppressed, and the AM-PM distortion of a radio-frequency signal amplified by the amplification transistor 11 can be suppressed without necessarily the influences of a temperature variation and a process variation (see FIG. 13C). Since the bias voltage vg1a refers to the bias voltage vg1r, the variation in the bias voltage vg1a due to the temperature variation and the process variation of the amplification transistor 11 can be suppressed.

### <2.2 Effects, Etc.>

As described above, an amplification circuit according to the present embodiment includes the amplification transistor 11 connected to the signal input terminal 110, the power supply circuit 22 configured to supply the bias voltage vg1a to the amplification transistor 11, the transistor 21 that is connected to the power supply circuit 22 and that is a simulated transistor for the amplification transistor, the detection diode 31 connected between the power supply circuit 22 and the signal input terminal 110, the diode replica 33 that is a simulated diode for the detection diode 31, and the difference detection circuit 34 that is connected between the power supply circuit 22 and each of the detection diode 31 and the diode replica 33 and that is configured to output a differential current between the current Irec flowing through the detection diode 31 and the current Idr flowing through the diode replica 33 to the power supply circuit 22.

With this configuration, the bias voltage vg1a obtained by adding a voltage corresponding to a differential current output from the difference detection circuit 34 to the bias voltage vg1r supplied to the transistor 21 is supplied to the amplification transistor 11. Accordingly, the decrease in the time average of the gate-to-source capacitance Cgs of the amplification transistor 11 at the time of the increase in the power of a radio-frequency signal is compensated for by the increase in the bias voltage vg1a. As a result, the variation in the characteristics of the detection diode 31 can be suppressed, and the AM-PM distortion of a radio-frequency signal amplified by the amplification transistor 11 can be suppressed without necessarily the influences of a temperature variation and a process variation. Since the bias voltage vg1a refers to the bias voltage vg1r, the variation in the bias voltage vg1a due to the temperature variation and the process variation of the amplification transistor 11 can be suppressed.

### Other Embodiments

An amplification circuit according to an embodiment and a communication device according to an embodiment have been described with the embodiments, the examples, and the modifications, but an amplification circuit according to the present disclosure and a communication device according to the present disclosure are not limited to the above embodiments, the above examples, and the above modifications. The present disclosure also includes other embodiments realized by combining optional constituent elements in the above embodiments, the above examples, and the above modifications, modifications obtained by making various changes, which are conceived by those skilled in the art, to the above embodiments, the above examples, and the above modifications without necessarily departing from the spirit and scope of the present disclosure, and various apparatuses including the above amplification circuit and the above communication device.

For example, in amplification circuits and communication devices according to the above embodiments, the above examples, and the above modifications, other circuit elements and other wiring lines may be inserted between the illustrated circuit elements and between the illustrated paths each connecting signal paths.

The characteristics of a radio-frequency module and a communication device described with reference to the above embodiments and the above modifications will be described below.

<1>

An amplification circuit comprising:
a first transistor that is connected to a radio-frequency input terminal and that is a field-effect transistor;
a power supply circuit configured to supply a bias voltage to the first transistor;
a first resistor disposed in series to a bias path connecting the power supply circuit and the first transistor;
a second transistor that is connected to the bias path and the power supply circuit and that is a simulated transistor for the first transistor; and
a first diode that connected to the radio-frequency input terminal and the bias path between the first resistor and a gate of the first transistor.
   <2>

The amplification circuit according to <1>, further comprising a second diode that is a simulated diode for the first diode and that is connected to the bias path between the first resistor and the power supply circuit.

<3>

The amplification circuit according to <2>, wherein the power supply circuit is configured such that a sum of a first current flowing through the first diode and a second current flowing through the second diode becomes a constant value.

<4>

The amplification circuit according to <2>, wherein the power supply circuit is configured such that a sum of a first current flowing through the first diode and a second current flowing through the second diode varies in accordance with at least one of parameters, a temperature of the amplification circuit, a power supply voltage applied to the first transistor, output power of the first transistor, an load impedance of the first transistor, a frequency of a radio-frequency signal, and a process variation.

<5>

The amplification circuit according to any one of <2> to <4>,
wherein a cathode of the first diode is connected to the gate of the first transistor,
wherein a first terminal of the first resistor is connected to a first node on a signal path connecting the radio-frequency input terminal and the gate of the first transistor,
wherein a second terminal of the first resistor is connected to a cathode of the second diode and a gate of the second transistor,
wherein the bias path includes the gate of the second transistor, the first resistor, the first node, and the gate of the first transistor, and
wherein the power supply circuit includes,
a third transistor having a gate, a drain, and a source, the gate being connected to a first current source circuit and a drain or a source of the second transistor, one of the drain and the source being connected to a voltage source, the other one of the drain and the source being connected to an anode of the first diode and an anode of the second diode, and
a second current source circuit connected between a ground and each of a cathode of the second diode and the second terminal of the first resistor.
   <6>

The amplification circuit according to any one of <2> to <4>,
wherein a cathode of the first diode is connected to the gate of the first transistor,
wherein a first terminal of the first resistor is connected to a first node on a signal path connecting the radio-frequency input terminal and the gate of the first transistor,
wherein a second terminal of the first resistor is connected to a cathode of the second diode and a gate of the second transistor,
wherein the bias path includes the gate of the second transistor, the first resistor, the first node, and the gate of the first transistor,
wherein the amplification circuit further comprises a first bias detection circuit, an error amplification circuit, and a second bias detection circuit,
wherein the error amplification circuit includes a comparator,
wherein the power supply circuit includes a third transistor, a fourth transistor, a second node, a third node, and a second current source circuit,
wherein the third transistor has a gate, a drain, and a source, the gate being connected to the second node, one of the drain and the source being connected to a voltage source, the other one of the drain and the source being connected to an anode of the first diode and an anode of the second diode,
wherein the fourth transistor is connected between the comparator and the second node,
wherein the second node is connected between the fourth transistor and the third node and between the fourth transistor and the second bias detection circuit,
wherein the third node is connected to a cathode of the second diode and the gate of the second transistor,
wherein the second current source circuit is connected between the third node and a ground,
wherein the first bias detection circuit is connected between a drain or a source of the second transistor and the comparator,
wherein the second bias detection circuit is connected between the second node and the third node, and
wherein the gate of the second transistor is connected to a gate of the first transistor.
   <7>

The amplification circuit according to <6>, further comprising a first variable resistance circuit connected between the second diode and the third node.

<8>

The amplification circuit according to <6>, further comprising a fifth transistor having a gate, a drain, and a source, the gate being connected to the second node, one of the drain and the source being connected to a voltage source, the other one of the drain and the source being connected to the anode of the first diode.

<9>

The amplification circuit according to any one of <5> to <8>, wherein the second current source circuit includes,
a first current circuit configured to generate a constant current,
a second current circuit configured to generate a variation current in accordance with a temperature,
a sixth transistor having a gate, a drain, and a source, the gate and one of the drain and the source being connected to the first current circuit,
a seventh transistor having a gate, a drain, and a source, the gate and the other one of the drain and the source being connected to the second current circuit,
an eighth transistor having a gate, a drain, and a source, the gate being connected to the gate of the sixth transistor, one of the drain and the source being connected to the cathode of the second diode and the second terminal of the first resistor, the other one of the drain and the source being connected to a ground, and
a ninth transistor having a gate, a drain, and a source, the gate being connected to the gate of the seventh transistor, one of the drain and the source being connected to the cathode of the second diode and the second terminal of the first resistor, the other one of the drain and the source being connected to a ground.
   <10>

The amplification circuit according to any one of <5> to <8>, wherein the second current source circuit includes,
a first current circuit configured to generate a constant current,
a sixth transistor having a gate, a drain, and a source, the gate and one of the drain and the source being connected to the first current circuit,
a seventh transistor having a gate, a drain, and a source, the gate being connected to the gate of the sixth transistor via a second switch, one of the drain and the source being connected to the cathode of the second diode and the second terminal of the first resistor, the other one of the drain and the source being connected to a ground, and
an eighth transistor having a gate, a drain, and a source, the gate being connected to the gate of the sixth transistor via a third switch, one of the drain and the source being connected to the cathode of the second diode and the second terminal of the first resistor, the other one of the drain and the source being connected to a ground.
   <11>

The amplification circuit according to any one of <1> to <10>, further comprising:
a tenth transistor that is a field-effect transistor;
a third diode; and
a first transformer including a primary side coil and a secondary side coil,
wherein at least one of a first end or a second end of the primary side coil is connected to the radio-frequency input terminal,
wherein a first end of the secondary side coil is connected to the gate of the first transistor,
wherein a second end of the secondary side coil is connected to a gate of the tenth transistor,
wherein a first terminal of the first resistor is connected to a second node of the secondary side coil, and a second terminal of the first resistor is connected to the power supply circuit,
wherein the bias path includes the power supply circuit, the first resistor, the secondary side coil, the gate of the first transistor, and the gate of the tenth transistor,
wherein a cathode of the first diode is connected to the bias path between the gate of the first transistor and the secondary side coil,
wherein a cathode of the third diode is connected to the bias path between the gate of the tenth transistor and the secondary side coil, and
wherein an anode of the first diode is connected to an anode of the third diode.
   <12>

The amplification circuit according to <11>, wherein the first resistor has a variable resistance value.

<13>

An amplification circuit comprising:
a first transistor that is connected to a radio-frequency input terminal and that is a field-effect transistor;
a power supply circuit configured to supply a bias voltage to the first transistor;
a second transistor that is connected to the power supply circuit and that is a simulated transistor for the first transistor;
a first diode connected between the power supply circuit and the radio-frequency input terminal;
a second diode that is a simulated diode for the first diode; and
a difference detection circuit that is connected between the power supply circuit and each of the first diode and the second diode and that is configured to output a differential current between a first current flowing through the first diode and a second current flowing through the second diode to the power supply circuit.
   <14>

A communication device comprising:
a signal processing circuit configured to process a radio-frequency signal; and
the amplification circuit according to any one of <1> to <13>, the amplification circuit being configured to transmit the radio-frequency signal between the signal processing circuit and an antenna.

The present disclosure is widely applicable to communication devices such as mobile phones as a power amplifier for amplifying a radio-frequency signal.

What is claimed is:

1. An amplification circuit comprising:
a first transistor that is connected to a radio-frequency input terminal and that is a field-effect transistor;
a power supply circuit configured to supply a bias voltage to the first transistor;
a first resistor in a bias path, the bias path connecting the power supply circuit and the first transistor;
a second transistor that is connected to the bias path and to the power supply circuit, the second transistor having a same configuration and a same or different size as the first transistor; and
a first diode that is connected to the radio-frequency input terminal and to the bias path between the first resistor and a gate of the first transistor.

2. The amplification circuit according to claim 1, further comprising a second diode that is connected to the bias path between the first resistor and the power supply circuit, the second diode having a same configuration and a same or different size as the first diode.

3. The amplification circuit according to claim 2, wherein the power supply circuit is configured such that a sum of a first current flowing through the first diode and a second current flowing through the second diode becomes a constant value.

4. The amplification circuit according to claim 2, wherein the power supply circuit is configured such that a sum of a first current flowing through the first diode and a second current flowing through the second diode varies in accordance with a temperature of the amplification circuit, a power supply voltage applied to the first transistor, an output power of the first transistor, a load impedance of the first transistor, a frequency of a radio-frequency signal, or a process variation.

5. The amplification circuit according to claim 2,
wherein a cathode of the first diode is connected to the gate of the first transistor,
wherein a first terminal of the first resistor is connected to a first node on a signal path, the signal path connecting the radio-frequency input terminal and the gate of the first transistor,
wherein a second terminal of the first resistor is connected to a cathode of the second diode and to a gate of the second transistor,
wherein the gate of the second transistor, the first resistor, the first node, and the gate of the first transistor are in the bias path, and
wherein the power supply circuit comprises:
a third transistor having a gate, a drain, and a source, the gate being connected to a first current source circuit and to a drain or a source of the second transistor, one of the drain and the source being connected to a voltage source, and the other one of the drain and the source being connected to an anode of the first diode and to an anode of the second diode, and
a second current source circuit connected between ground and each of a cathode of the second diode and the second terminal of the first resistor.

6. The amplification circuit according to claim 2,
wherein a cathode of the first diode is connected to the gate of the first transistor,
wherein a first terminal of the first resistor is connected to a first node on a signal path, the signal path connecting the radio-frequency input terminal and the gate of the first transistor,
wherein a second terminal of the first resistor is connected to a cathode of the second diode and to a gate of the second transistor,
wherein the gate of the second transistor, the first resistor, the first node, and the gate of the first transistor are in the bias path,
wherein the amplification circuit further comprises a first bias detection circuit, an error amplification circuit, and a second bias detection circuit,
wherein the error amplification circuit comprises a comparator,
wherein the power supply circuit comprises a third transistor, a fourth transistor, a second node, a third node, and a second current source circuit,
wherein the third transistor has a gate, a drain, and a source, the gate being connected to the second node, one of the drain and the source being connected to a voltage source, and the other one of the drain and the source being connected to an anode of the first diode and to an anode of the second diode,
wherein the fourth transistor is connected between the comparator and the second node,
wherein the second node is connected between the fourth transistor and the third node, and between the fourth transistor and the second bias detection circuit,
wherein the third node is connected to a cathode of the second diode and to the gate of the second transistor,
wherein the second current source circuit is connected between the third node and ground,
wherein the first bias detection circuit is connected between a drain or a source of the second transistor and the comparator,
wherein the second bias detection circuit is connected between the second node and the third node, and
wherein the gate of the second transistor is connected to a gate of the first transistor.

7. The amplification circuit according to claim 6, further comprising a first variable resistance circuit connected between the second diode and the third node.

8. The amplification circuit according to claim 6, further comprising a fifth transistor having a gate, a drain, and a source, the gate being connected to the second node, one of the drain and the source being connected to a voltage source, and the other one of the drain and the source being connected to the anode of the first diode.

9. The amplification circuit according to claim 5, wherein the second current source circuit comprises:
a first current circuit configured to generate a constant current;
a second current circuit configured to generate a variation current in accordance with a temperature;
a sixth transistor having a gate, a drain, and a source, the gate and one of the drain and the source being connected to the first current circuit;
a seventh transistor having a gate, a drain, and a source, the gate and the other one of the drain and the source being connected to the second current circuit;
an eighth transistor having a gate, a drain, and a source, the gate being connected to the gate of the sixth transistor, one of the drain and the source being connected to the cathode of the second diode and to the second terminal of the first resistor, and the other one of the drain and the source being connected to ground; and
a ninth transistor having a gate, a drain, and a source, the gate being connected to the gate of the seventh transistor, one of the drain and the source being connected to the cathode of the second diode and to the second terminal of the first resistor, and the other one of the drain and the source being connected to ground.

10. The amplification circuit according to claim 5, wherein the second current source circuit comprises:
a first current circuit configured to generate a constant current,
a sixth transistor having a gate, a drain, and a source, the gate and one of the drain and the source being connected to the first current circuit,
a seventh transistor having a gate, a drain, and a source, the gate being connected to the gate of the sixth transistor via a second switch, one of the drain and the source being connected to the cathode of the second diode and to the second terminal of the first resistor, and the other one of the drain and the source being connected to ground, and
an eighth transistor having a gate, a drain, and a source, the gate being connected to the gate of the sixth transistor via a third switch, one of the drain and the source being connected to the cathode of the second diode and to the second terminal of the first resistor, the other one of the drain and the source being connected to ground.

11. The amplification circuit according to claim 1, further comprising:
a tenth transistor that is a field-effect transistor;
a third diode; and
a first transformer comprising a primary side coil and a secondary side coil,
wherein a first end or a second end of the primary side coil is connected to the radio-frequency input terminal,
wherein a first end of the secondary side coil is connected to the gate of the first transistor,
wherein a second end of the secondary side coil is connected to a gate of the tenth transistor,
wherein a first terminal of the first resistor is connected to a second node of the secondary side coil, and a second terminal of the first resistor is connected to the power supply circuit,
wherein the power supply circuit, the first resistor, the secondary side coil, the gate of the first transistor, and the gate of the tenth transistor are in the bias path,
wherein a cathode of the first diode is connected to the bias path between the gate of the first transistor and to the secondary side coil,
wherein a cathode of the third diode is connected to the bias path between the gate of the tenth transistor and the secondary side coil, and
wherein an anode of the first diode is connected to an anode of the third diode.

12. The amplification circuit according to claim 11, wherein the first resistor has a variable resistance value.

13. An amplification circuit comprising:
a first transistor that is connected to a radio-frequency input terminal and that is a field-effect transistor;
a power supply circuit configured to supply a bias voltage to the first transistor;
a second transistor that is connected to the power supply circuit, the second transistor having a same configuration and a same or different size as the first transistor;
a first diode connected between the power supply circuit and the radio-frequency input terminal;
a second diode that has a same configuration and a same or different size as the first diode; and
a difference detection circuit that is connected between the power supply circuit and each of the first diode and the second diode, and that is configured to output a differential current between a first current flowing through the first diode and a second current flowing through the second diode to the power supply circuit.

14. A communication device comprising:
a signal processing circuit configured to process a radio-frequency signal; and
the amplification circuit according to claim 1, the amplification circuit being configured to transmit the radio-frequency signal between the signal processing circuit and an antenna.
